(19) United States
(12) Patent Application Publication
(10) Pub. No.: US 2026/0031765 A1
(43) Pub. Date: Jan. 29, 2026

(54) MULTI-INPUT RF LNA WITH UNIFIED FEEDBACK PATH AND PASSIVE GAIN PATH SYSTEMS AND METHODS

(71) Applicant: pSemi Corporation, San Diego, CA (US)

(72) Inventors: Xiaoling Guo, Austin, TX (US); Shilpi Sharma, Leander, TX (US); Jing Li, Austin, TX (US); Sivakumar Ganesan, Austin, TX (US)

(21) Appl. No.: 18/784,783

(22) Filed: Jul. 25, 2024

(51) Int. Cl. H03F 1/26; H03F 1/22; H03F 3/193

(52) U.S. Cl. CPC H03F 1/26; H03F 3/193; H03F 1/223; H03F 2200/156; H03F 2200/294; H03F 2200/451

(57) ABSTRACT

Circuits and methods include amplification circuitry coupled to a plurality of input signal paths and an output signal path and a unified signal path combining a feedback path couplable between a feedback node in the output signal path and the input signal path via a plurality of input switches and a passive gain path couplable between the feedback node in the output signal path and one or more input signal paths through the input switch. The circuit may include a first capacitor and a variable resistor coupled in series and a second capacitor coupled in series with a feedback path switch and a power supply rejection resistor. The passive gain path may further include a shunt switch coupled in series between a plurality of bypass switches to form a T-switch. A fast charging switch may be configurable to couple a second capacitor to a reference potential during a state change of the unified signal path.

### BACKGROUND

### (1) Technical Field

The present disclosure relates to electronic circuits, and more particularly, for example, to radio frequency amplifier circuits.

### (2) Background

Many modern electronic systems include radio frequency (RF) receivers including, for example, cellular telephones, personal computers, tablet computers, wireless network components, televisions, cable system “set top” boxes, radar systems, and the like. Many RF receivers are paired with RF transmitters in the form of transceivers providing two-way radio communications. In some cases, RF transceivers are capable of transmitting and receiving across multiple frequencies in multiple bands.

Amplifiers are a common component in RF transmitters, receivers, and transceivers, and are frequently used for power amplification of transmitted RF signals and for low-noise amplification of received RF signals. For many RF systems, such as those designed for low power operation and/or mobile operation (e.g., mobile phones, vehicles, WiFi-connected computers, cameras, and other devices), it has become common to use complementary metal-oxide semiconductor (CMOS) fabrication technology to create low cost, low power integrated circuits (ICs). CMOS devices include bulk CMOS, silicon-on-insulator (SOI) CMOS, and silicon-on-sapphire (SOS) CMOS (SOS being a type of SOI fabrication technology).

In many implementations, desired characteristics of an LNA are high gain with low noise, a wide bandwidth, good linearity, and good output impedance matching. Accordingly, design parameters for LNAs may include gain, noise figure (NF), input-referenced third intercept point (IIP3), and output reflection coefficient. NF is a measure of degradation of the signal-to-noise ratio (SNR) caused by components in a signal chain, with lower values indicating better performance. IIP3 is a figure representing amplifier linearity, with higher values indicating better performance. In general, NF has a stricter specification requirement in high-gain modes than in low gain-modes, while IIP3 usually has a higher specification requirement in low-gain modes than in high-gain modes. The output reflection coefficient is the S22 scattering parameter (or “S-parameter”) and is an indication of output impedance matching, with lower (more negative, when evaluated logarithmically) numbers indicating better impedance matching.

Increases in the frequency of RF communications bands and channels, as well as a continuing increase in the number of bands and channels in use, has pushed current LNA architectures to their limits. For example, achieving stringent requirements for gain, percentage bandwidth, linearity, and output impedance matching with a traditional LNA architecture is not possible for some of the new 5G mobile network bands, particularly in the 3 to 6 GHz NR bands, 7-24 GHz bands, and the millimeter wave range (e.g., 24.25 GHz to 52.6 GHZ).

In view of the foregoing, there is a continued need for improved LNA architectures that overcome and/or improve upon one or more limitations of conventional LNA architectures.

### SUMMARY

The present disclosure encompasses frequency-selective circuits and methods for an amplifier (such as LNAs) that achieve improved performance in feedback circuits. The disclosed circuits and methods may also be applied to other types of amplifiers, such as power amplifiers.

In various embodiments, circuits and methods include a first amplification core including a first input terminal coupled to a first input signal path and a first output terminal coupled to an output signal path; and a unified feedback path including a feedback path coupled between a feedback node in the output signal path and the first input signal path via a first input signal path switch, the feedback path comprising feedback path switches configurable to couple and/or decouple the feedback path to the first input signal path switch, and a passive gain path couplable between the feedback node in the output signal path and the first input signal path via the first input signal path switch, the passive gain path configurable through passive gain path switches to couple and/or decouple the passive gain path to the first input signal path switch. The first input signal path switch may be configured to couple the unified feedback path to the first input terminal.

In some embodiments, the first amplification core is one of a plurality of amplification cores, the first input signal path is one of a plurality of input signal paths, and the first input signal path switch is one of a plurality of input switches. Each of the plurality of amplification cores may include an amplification core input terminal coupled to a corresponding one of the plurality of input signal paths, and each of the plurality of input switches may be configured to connect the unified feedback path to a corresponding one of the plurality of amplification cores.

In some embodiments, the unified feedback path further includes a first capacitor, and the feedback path includes a variable resistor coupled in series with the first capacitor, and the feedback path switches may be coupled in series with the variable resistor. The circuit may further include a second capacitor coupled in series with the feedback path switches and a power supply rejection resistor coupled to a node on the feedback path and configured to be coupled to a reference potential. The passive gain path may further include a shunt switch coupled in series between a plurality of bypass switches to form a T-switch.

In some embodiments, the first input signal path switch is coupled in series to the second capacitor via a first node, and the circuit further includes a fast charging switch coupled in series between the first node and a reference potential. The second capacitor may be coupled between the first node and an LNA input voltage, with the fast charging switch configurable to connect the second capacitor to the reference potential during a state change of the unified feedback path to facilitate stabilization of the second capacitor. The fast charging switch may be configurable to decouple the capacitor from the reference potential after the second capacitor has a stabilized voltage.

In some embodiments of the circuits and methods are configurable to operate the unified feedback path in a plurality of modes including a high gain mode where the feedback path switches are open and the passive gain path switches are open, a low gain mode where the feedback path switches are closed and the passive gain path switches are open, and/or a passive gain mode where the feedback path switches are open and the passive gain path switches are closed.

The details of one or more embodiments of the disclosure are set forth in the accompanying drawings and the description below. Other features, objects, and advantages of the disclosure will be apparent from the description and drawings, and from the claims.

### DESCRIPTION OF THE DRAWINGS

FIG. 1 is a simplified schematic diagram of an embodiment of an LNA circuit.

FIG. 2 is a simplified schematic diagram of a more detailed embodiment of the input matching feedback circuit of FIG. 1.

FIG. 3 is a simplified schematic diagram of an embodiment of an LNA circuit in accordance with the present disclosure.

FIG. 4 is a graph of voltage as a function of frequency for modeled embodiments of the LNA circuit of FIG. 1 and the LNA circuit of FIG. 3.

FIG. 5 is a top plan view of a substrate that may be, for example, a printed circuit board or chip module substrate (e.g., a thin-film tile).

FIG. 6 illustrates a wireless communication environment including different wireless communication systems and may include one or more mobile wireless devices incorporating an LNA circuit of FIGS. 1-5 and/or 7-11, in accordance with the present disclosure.

FIG. 7 is a block diagram of a transceiver that might be used in a wireless device, such as a cellular telephone, and which may beneficially incorporate an embodiment of the present disclosure.

FIG. 8 is a process flow chart illustrating a method of improving amplifier performance, in accordance with the present disclosure.

FIG. 9 is a simplified schematic diagram of an embodiment of a multi-input LNA circuit in accordance with the present disclosure.

FIG. 10 is a simplified schematic diagram of an embodiment of a multi-input LNA circuit in accordance with the present disclosure.

FIG. 11 is a process flow chart showing a method of improving LNA circuit performance in accordance with the present disclosure.

FIG. 12 illustrates an example operational configurations for switches of an LNA circuit with unified feedback and passive gain paths, in accordance with the present disclosure.

Like reference numbers and designations in the various drawings indicate like elements unless the context requires otherwise.

### DETAILED DESCRIPTION

The present disclosure provides improved circuits and methods for an amplifier (such as an LNA) that may include multiple radio-frequency inputs. In some embodiments, a multi-input LNA circuit includes a unified active gain/passive gain feedback path that may be coupled to each of the RF inputs through one or more switches, providing improved RF performance that provides advantages (e.g., reduced parasitics) over conventional approaches. The circuits and methods disclosed herein may also be applied to other types of amplifiers, such as power amplifiers, and circuits within the spirit and scope of the present disclosure.

In the detailed description that follows, various single-input amplifier embodiments will first be described followed by embodiments illustrating multi-input amplifiers with unified active gain and passive gain feedback path implementations.

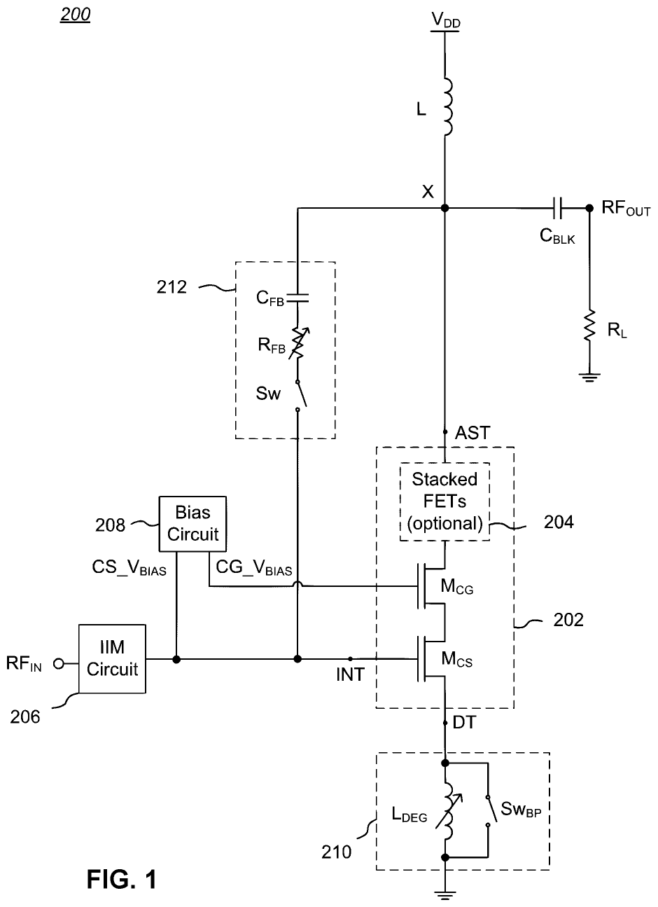

FIG. 1 is a simplified schematic diagram of an embodiment of an LNA circuit 200. The LNA circuit 200 includes an amplification core 202 that includes a common-source FET M_{CS} and a common-gate FET M_{CG} series-connected through their respective conduction channels (between drain and source) in a cascode arrangement. The gate of the common-source FET M_{CS} may be regarded as an input terminal INT of the amplification core 202, the source of the common-source FET M_{CS} may be regarded as a degeneration terminal DT of the amplification core 202, and the drain of the common-gate FET Meg may be regarded as an amplified-signal terminal AST of the amplification core 202. In some embodiments, to overcome a relatively low breakdown voltage per CMOS FET, multiple common-gate FETS may be series-coupled through their respective conduction channels in a FET stack 204 between the drain of the bottom-most common-gate FET M_{CG} and the amplified-signal terminal AST—that is, the amplification core 202 may have multiple series-coupled common-gate FETs in a cascode configuration. The amplified-signal terminal AST would then be the drain of the upper-most common-gate FET in the amplification core 202.

An RF input signal applied to an RF input terminal RF_{IN} may be passed through an input impedance matching circuit 206 and coupled to the input terminal INT of the amplification core 202. A bias circuit 208 is configured to provide a suitable bias voltage CG_V_{BIAS} to the common-gate FET M_{CG} and a suitable bias voltage CS_V_{BIAS} to the common-source FET M_{CS}. The bias circuit 208 or a separate bias source (not shown) may provide a suitable bias voltage or voltages to the constituent FETs within the FET stack 204.

The amplified-signal terminal AST provides an amplified RF output signal through a DC blocking capacitor C_{BLK} to an RF output terminal RF_{OUT}. Adjustable capacitor C_{BLK} may also aid in providing output impedance matching. A bias-isolating inductor L is connected between a source voltage V_{DD} and the amplified-signal terminal AST to aid in providing output impedance matching and to provide a bias feed to the amplifier core 202. In the illustrated example, the RF output terminal RF_{OUT} is shown coupled to a typical load, represented as a resistor R_{L}. The value of R_{L} is typically 50 ohms for many modern RF circuits.

The degeneration terminal DT may be coupled through a degeneration circuit 210 to a reference potential, such as circuit ground. In some embodiments, the degeneration circuit 210 may include an adjustable degeneration inductor L_{DEG}, such as a multiport integrated circuit inductor coil. An adjustable degeneration inductor L_{DEG} may be used to improve linearity in low gain modes. For example, a smaller value for the degeneration inductor L_{DEG} may be used in a higher-gain modes, and a larger value for the degeneration inductor L_{DEG} may be used in a lower-gain modes. Some embodiments of the degeneration circuit 210 may include a bypass switch SW_{BP} coupled in parallel with the degeneration inductor L_{DEG}.

The illustrated embodiment includes an input matching feedback circuit 212. The input matching feedback circuit 212 is shown coupled between the input terminal INT and the amplified-signal terminal AST of the amplifier core 202. More generally, the input matching feedback circuit 212 may be coupled to a feedback node in the output signal path of the amplification core 202, which may be the drain of any of the FETS in the amplification core 202. The choice of feedback node for connection to the input matching feedback circuit 212 may be made, for example, based on desired feedback strength and/or input impedance.

The input matching feedback circuit 212 in the illustrated embodiment includes a DC-blocking/AC-coupling capacitor C_{FB} series-coupled to a variable resistor R_{FB}, which in turn is series-coupled to a switch Sw. The capacitor C_{FB}, the resistor R_{FB}, and the switch Sw may be connected in any series order in alternative embodiments, although a specific order may be preferred in some applications from a biasing perspective and/or to reduce the impact of related parasitics. In some embodiments, the capacitor C_{FB} may be adjustable. The input matching feedback circuit 212 may be disabled by opening switch Sw and enabled by closing switch Sw. In alternative embodiments, the switch Sw may be omitted, thereby permanently coupling the input matching feedback circuit 212 between the input terminal INT and a feedback node in the output signal path of the amplification core 202.

The resistance value of the variable resistor R_{FB} allows the Q-factor of the input impedance matching to be adjusted, which allows variation in the bandwidth of the enhanced LNA circuit 200 (with trade-offs with respect to gain and NF). Thus, an advantage of using a variable or multi-state input matching feedback circuit 212 is that multiple resistance values enable multiple gain modes. For instance, LNAs in mobile RF receiver devices need multiple gain modes depending upon the range of input signal strength at the receiver. In addition, enabling multiple gain modes by varying the resistance value of resistor R_{FB} may eliminate the need for an output attenuator (common in conventional receiver LNAs).

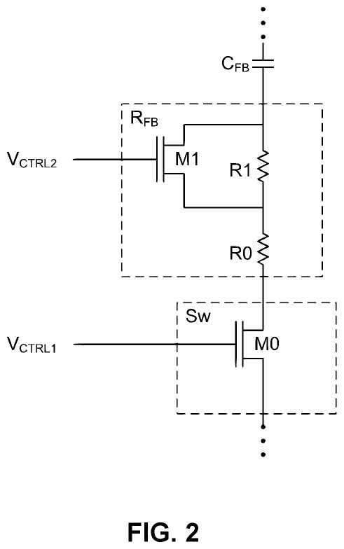

FIG. 2 is a simplified schematic diagram of a more detailed embodiment of the input matching feedback circuit 212 of FIG. 1. The switch Sw is depicted as a FET M0 having its gate coupled to a control signal V_{CTRL1}. The variable resistor R_{FB} may be implemented as a first resistor R0 coupled in series with a second resistor R1. A FET M1 is coupled in parallel with the second resistor R1 and has its gate coupled to a control signal V_{CTRL2}. Accordingly, when the control signal V_{CTRL2} sets M1 to an OFF (non-conducting) state, the resistance of the variable resistor R_{FB} is R0+R1. Conversely, when the control signal V_{CTRL2} sets M1 to an ON (conducting) state, the resistance of the variable resistor R_{FB} is about R0 (neglecting the ON resistance R_{ON} of M1). The variable resistor R_{FB} may be implemented in a number of ways that allow for selection of more than two resistance values. For example, adding another separately controlled bypassable resistor in series with resistors R0 and R1 allows for selection of four resistance values. As another example, one or more bypassable resistors may be coupled in parallel with resistor R0 and/or resistor R1.

Further information regarding the input matching feedback circuit 212 may be found in U.S. patent application Ser. No. 17/337,227, filed Jun. 2, 2021, entitled “Wideband Multi Gain LNA Architecture”, assigned to the assignee of the present disclosure, the contents of which are hereby incorporated by reference.

Performance of the LNA circuit 200 of FIG. 1 can be further improved to mitigate an issue that may arise when using an input matching feedback circuit 212. In particular, an LNA having an input matching feedback circuit 212 may suffer from poor rejection of low-frequency noise generated by internal and/or external voltage supplies. For example, such voltage supplies may include the source voltage V_{DD}, an internal charge pump generating a voltage V_{CP}, or other source voltage used to power the control signals (e.g., V_{CTRL1} and V_{CTRL2} in FIG. 2) for a variable resistor R_{FB}. Such noise may be sufficiently low in frequency (e.g., less than 100 MHz, and particularly less than 10 MHz) that noise signal leakage to the input of the LNA circuit 200 may occur through, for example, noise filtering capacitors.

The input of an LNA is particularly sensitive to such low-frequency noise. For example, low-frequency noise coupled to the input terminal INT of the amplification core 202 may be upconverted through a non-linearity of an LNA to RF frequencies and may cause a reduction of the Signal-to-Noise Ratio (SNR) at the output of the LNA. As another example, low-frequency noise coupled to the input terminal INT of the amplification core 202 may cause slow settling times of the quiescent bias-point of the LNA during LNA turn-ON and LNA turn-OFF, or other quiescent bias-point changing events.

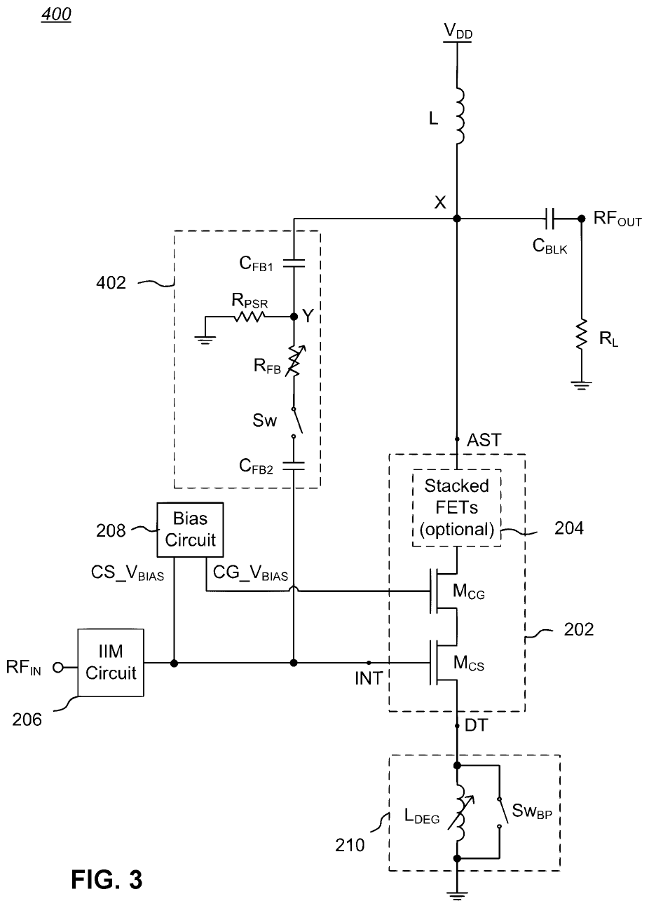

FIG. 3 is a simplified schematic diagram of another embodiment of an LNA circuit 400 in accordance with the present disclosure. Similar in most aspects to the LNA circuit 200 in FIG. 1, the LNA circuit 400 replaces the input matching feedback circuit 212 of FIG. 1 with an improved input matching feedback circuit 402.

The input matching feedback circuit 402 is shown coupled between the input terminal INT and the amplified-signal terminal AST of the amplifier core 202. More generally, the input matching feedback circuit 402 may be coupled to a feedback node in the output signal path of the amplification core 202, which may be the drain of any of the FETS in the amplification core 202. The choice of feedback node for connection to the input matching feedback circuit 402 may be made, for example, based on desired feedback strength and/or input impedance.

The input matching feedback circuit 402 in the illustrated embodiment includes a DC-blocking/AC-coupling first capacitor C_{FB1} series-coupled to a variable resistor R_{FB}. The variable resistor R_{FB} in turn is series-coupled to a switch Sw, which in turn is series-coupled to a DC-blocking/AC-coupling second capacitor C_{FB2}. The first capacitor C_{FB1}, the variable resistor R_{FB}, the switch Sw, and the second capacitor C_{FB2} define a feedback signal path through the input matching feedback circuit 402.

A PSR resistor R_{PSR} is coupled between the feedback signal path of the input matching feedback circuit 402 and a reference potential, which may be circuit ground. For example, FIG. 3 shows the PSR resistor R_{PSR} as being coupled to the feedback signal path between (1) a node Y, located between the first capacitor C_{FB1} and the variable resistor R_{FB}, and (2) the reference potential. It has been found that the illustrated location for connecting the PSR resistor R_{PSR} to the feedback signal path provides good amplifier performance. However, the PSR resistor R_{PSR} may be coupled to other locations along the feedback signal path, such as between the variable resistor R_{FB} and switch Sw, or between switch Sw and the second capacitor C_{FB2}.

In some embodiments, the first and/or second capacitors C_{FB1}, C_{FB2} may be adjustable. The input matching feedback circuit 402 may be placed in a disabled state by opening switch Sw and placed in an enabled state by closing switch Sw. In alternative embodiments, the switch Sw may be omitted, thereby permanently coupling the input matching feedback circuit 402 between the input terminal INT and a feedback node in the output signal path of the amplification core 202.

The PSR resistor R_{PSR} provides a low-impedance signal path to the reference potential for low-frequency noise from voltage supplies (e.g., V_{CP}, V_{DD}, or other supply voltage) that might otherwise be coupled through the feedback signal path to the input terminal INT of the amplification core 202. For example, the control signals (V_{CTRL1}, V_{CTRL2}) for the variable resistor R_{FB} may cause low-frequency noise from the V_{CP} voltage supply to be coupled to the input terminal INT. The PSR resistor R_{PSR} may be designed to not load the feedback signal path and the output of the LNA circuit 400 to maintain RF performance. For example, the PSR resistor R_{PSR} may have a resistance value in the range of about 1 KΩ to about 100 KΩ.

In one embodiment, the series-coupled first and second capacitors C_{FB1}, C_{FB2} each have about twice the capacitance value of the capacitor C_{FB} of the LNA 200 of FIG. 1; that is, C_{FB1}=C_{FB2}=2×C_{FB}, resulting in an equivalent capacitance of just C_{FB}. For example, C_{FB} may be in the range of about 0.1 pF to about 10 pF; thus, C_{FB1} and C_{FB2} would preferably have twice the capacitance value selected from that range, and thus be in the range of about 0.2 pF to about 20 pF. However, in some embodiments, the values of the first and second capacitors C_{FB1}, C_{FB2} may be other than 2×C_{FB}.

The splitting of the AC-coupling capacitor in the feedback signal path of the input matching feedback circuit 402 compared to the LNA 200 of FIG. 1 can also improve filtering of any low-frequency voltage supply noise coupled to the feedback signal path, such as through the control signals (e.g., V_{CTRL1} and V_{CTRL2}) for the variable resistor R_{FB}. The second capacitor C_{FB2} coupled closest to the RF input terminal RF_{IN} may be sized, for example, to present a high impedance at low frequencies compared to the impedance of the PSR resistor R_{PSR} so as to direct low frequency noise to the reference potential through the PSR resistor R_{PSR}. The input matching feedback circuit 402 may be used in other LNA and amplifier topologies and is not limited to the topology of the performance LNA circuit 400 of FIG. 3.

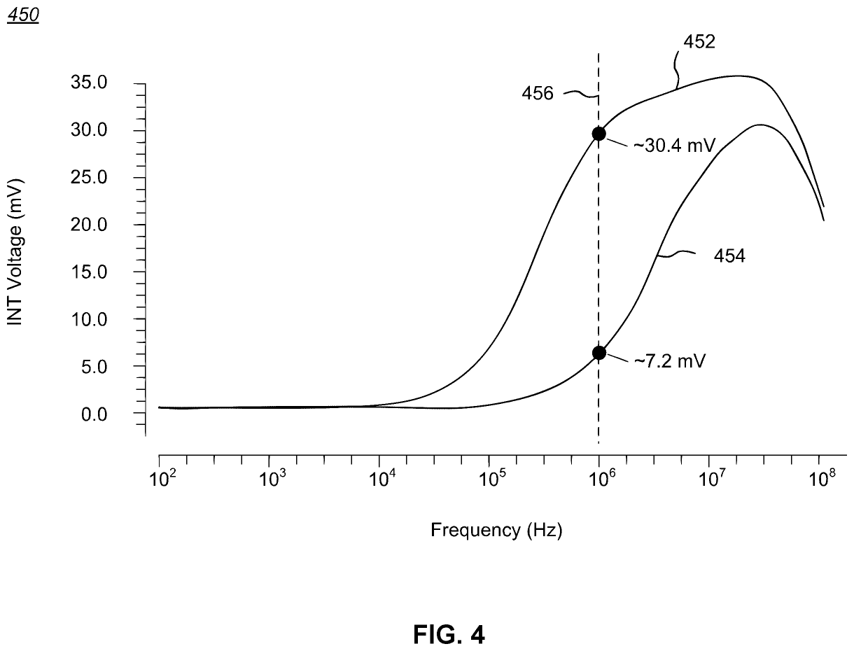

FIG. 4 is a graph 450 of voltage as a function of frequency for modeled embodiments of the LNA circuit 200 of FIG. 1 and the performance LNA circuit 400 of FIG. 3. The voltage is measured at the input terminal INT of the amplification core 202 when a 100 mV AC signal is applied at V_{DD}. Graph line 452 represents the response of the LNA circuit 200 of FIG. 2, and graph line 454 represents the response of the LNA circuit 400 of FIG. 3. Dashed marker line 456 shows the corresponding voltages at a frequency of about 1 MHZ—the LNA circuit 200 experiences a feedback leakage voltage of about 30.4 mV, while the LNA circuit 400 experiences a feedback leakage voltage of only about 7.2 mV, a factor of 4 improvement. As the graph 450 shows, at all frequencies, the performance LNA circuit 400 exhibits lower leakage voltage to the input terminal INT of the amplification core 202 compared to the LNA circuit 200 of FIG. 1.

Circuits and devices in accordance with the present disclosure may be used alone or in combination with other components, circuits, and devices. Embodiments of the present disclosure may be fabricated as integrated circuits (ICs), which may be encased in IC packages and/or in modules for ease of handling, manufacture, and/or improved performance. In particular, IC embodiments of this disclosure are often used in modules in which one or more of such ICs are combined with other circuit components or blocks (e.g., filters, amplifiers, passive components, and possibly additional ICs) into one package. The ICs and/or modules are then typically combined with other components, often on a printed circuit board, to form part of an end product such as a cellular telephone, laptop computer, or electronic tablet, or to form a higher-level module which may be used in a wide variety of products, such as vehicles, test equipment, medical devices, etc. Through various configurations of modules and assemblies, such ICs typically enable a mode of communication, often wireless communication.

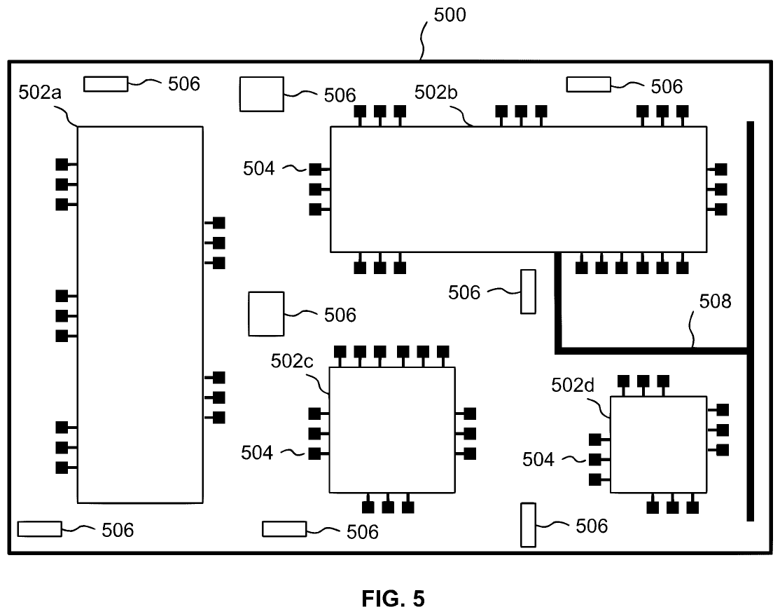

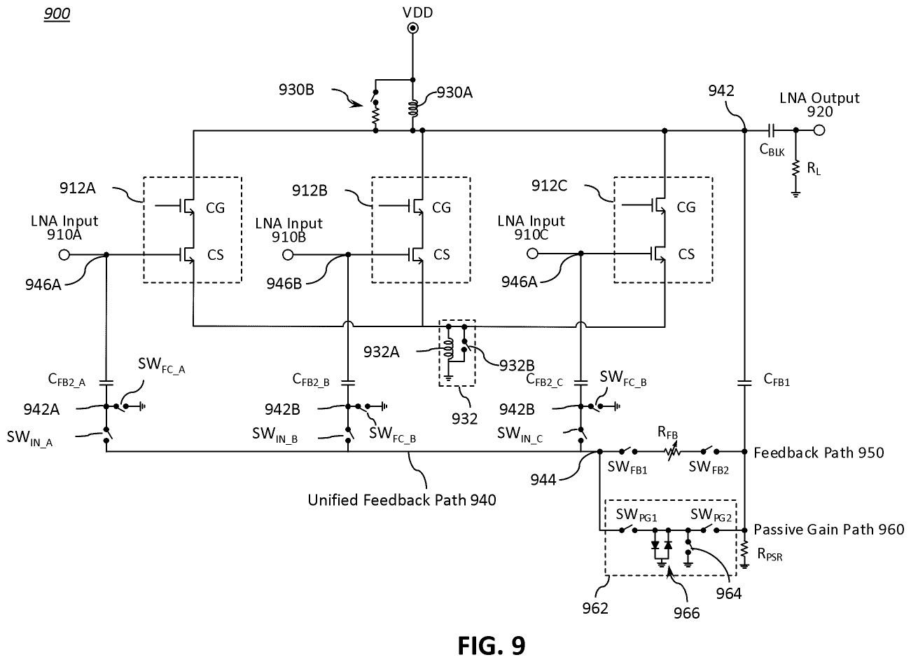

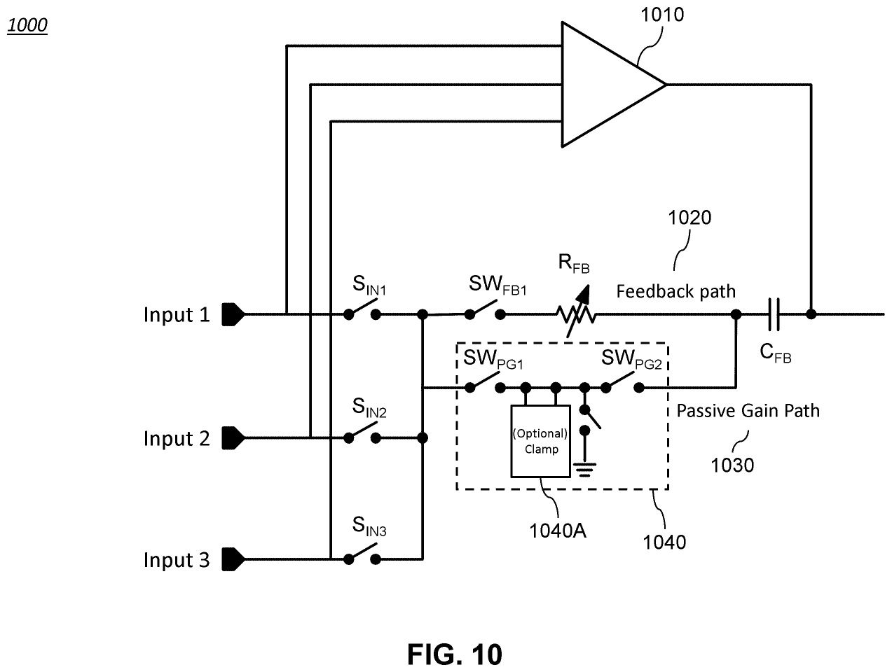

As one example of further integration of embodiments of the present disclosure with other components, FIG. 5 is a top plan view of a substrate 500 that may be, for example, a printed circuit board or chip module substrate (e.g., a thin-film tile). In the illustrated example, the substrate 500 includes multiple ICs 502a-502d having terminal pads 504 which would be interconnected by conductive vias and/or traces on and/or within the substrate 500 or on the opposite (back) surface of the substrate 500 (to avoid clutter, the surface conductive traces are not shown and not all terminal pads are labelled). The ICs 502a-502d may embody, for example, signal switches, active or passive filters, amplifiers (including one or more LNAs), and other circuitry. For example, IC 502b may incorporate one or more instances of an LNA circuit like the LNA circuit 400 shown in FIG. 3, LNA circuit 900 shown in FIG. 9, LNA circuit 1000 shown in FIG. 10, and other circuits disclosed herein.

The substrate 500 may also include one or more passive devices 506 embedded in, formed on, and/or affixed to the substrate 500. While shown as generic rectangles, the passive devices 506 may be, for example, filters, capacitors, inductors, transmission lines, resistors, planar antennae elements, transducers (including, for example, MEMS-based transducers, such as accelerometers, gyroscopes, microphones, pressure sensors, etc.), batteries, etc., interconnected by conductive traces on or in the substrate 500 to other passive devices 506 and/or the individual ICs 502a-502d.

The front or back surface of the substrate 500 may be used as a location for the formation of other structures. For example, one or more antennae may be formed on or affixed to the front or back surface of the substrate 500; one example of a front-surface antenna 508 is shown, coupled to an IC 502b (e.g., an IC die), which may include RF front-end circuitry. Thus, by including one or more antennae on the substrate 500, a complete radio may be created.

Embodiments of the present disclosure are useful in a wide variety of larger radio frequency (RF) circuits and systems, such as radio systems (particularly including cellular radio systems), personal computers, tablet computers, wireless network components, televisions, cable system “set top” boxes, radar systems (including phased array and automotive radar systems), and test equipment.

Radio system usage includes wireless RF systems (including base stations, relay stations, and hand-held transceivers) that use various technologies and protocols, including various types of orthogonal frequency-division multiplexing (“OFDM”), quadrature amplitude modulation (“QAM”), Code-Division Multiple Access (“CDMA”), Time-Division Multiple Access (“TDMA”), Wide Band Code Division Multiple Access (“W-CDMA”), Global System for Mobile Communications (“GSM”), Long Term Evolution (“LTE”), 5G New Radio, and WiFi (e.g., 802.11a, b, g, ac, ax, be), as well as other radio communication standards and protocols.

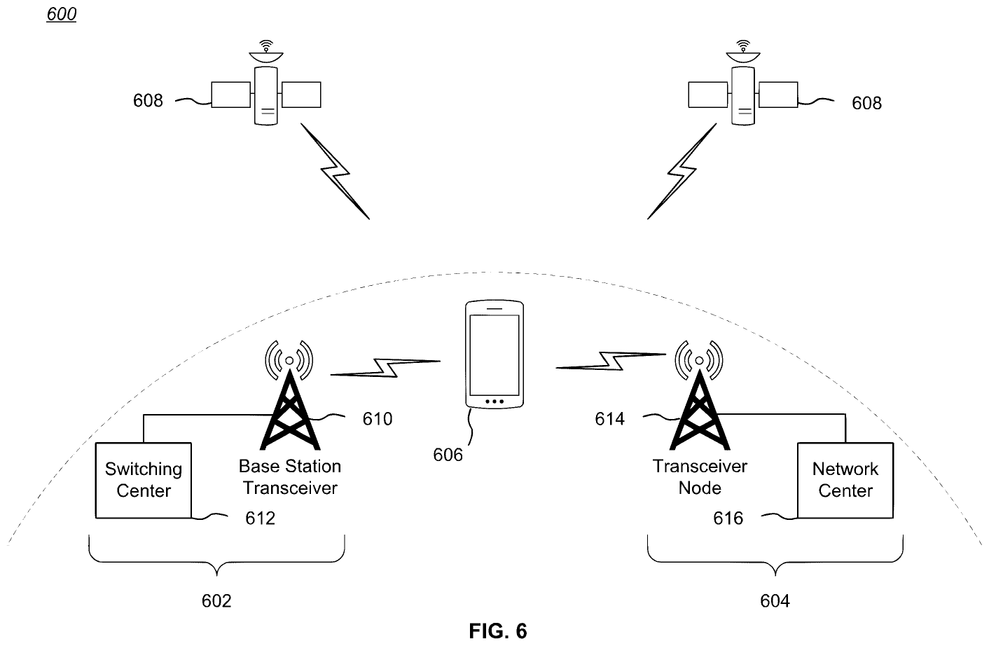

As an example of wireless RF system usage, FIG. 6 illustrates an example wireless communication environment 600 including different wireless communication systems 602 and 604 and may include one or more mobile wireless devices 606, that may include one or more amplification circuits disclosed herein in FIGS. 1-5 and 9-12.

A wireless device 606 may be capable of communicating with multiple wireless communication systems 602, 604 using one or more of the telecommunication protocols noted above. A wireless device 606 also may be capable of communicating with one or more satellites 608, such as navigation satellites (e.g., GPS) and/or telecommunication satellites. The wireless device 606 may be equipped with multiple antennas, externally and/or internally, for operation on different frequencies and/or to provide diversity against deleterious path effects such as fading and multi-path interference. A wireless device 606 may be a cellular phone, a personal digital assistant (PDA), a wireless-enabled computer or tablet, or some other wireless communication unit or device. A wireless device 606 may also be referred to as a mobile station, user equipment, an access terminal, or some other terminology.

The wireless system 602 may be, for example, a CDMA-based system that includes one or more base station transceivers (BSTs) 610 and at least one switching center (SC) 612. Each BST 610 provides over-the-air RF communication for wireless devices 606 within its coverage area. The SC 612 couples to one or more BSTs in the wireless system 602 and provides coordination and control for those BSTs.

The wireless system 604 may be, for example, a TDMA-based system that includes one or more transceiver nodes 614 and a network center (NC) 616. Each transceiver node 614 provides over-the-air RF communication for wireless devices 606 within its coverage area. The NC 616 couples to one or more transceiver nodes 614 in the wireless system 604 and provides coordination and control for those transceiver nodes 614.

In general, each BST 610 and transceiver node 614 is a fixed station that provides communication coverage for wireless devices 606 and may also be referred to as base stations or some other terminology. The SC 612 and the NC 616 are network entities that provide coordination and control for the base stations and may also be referred to by other terminologies.

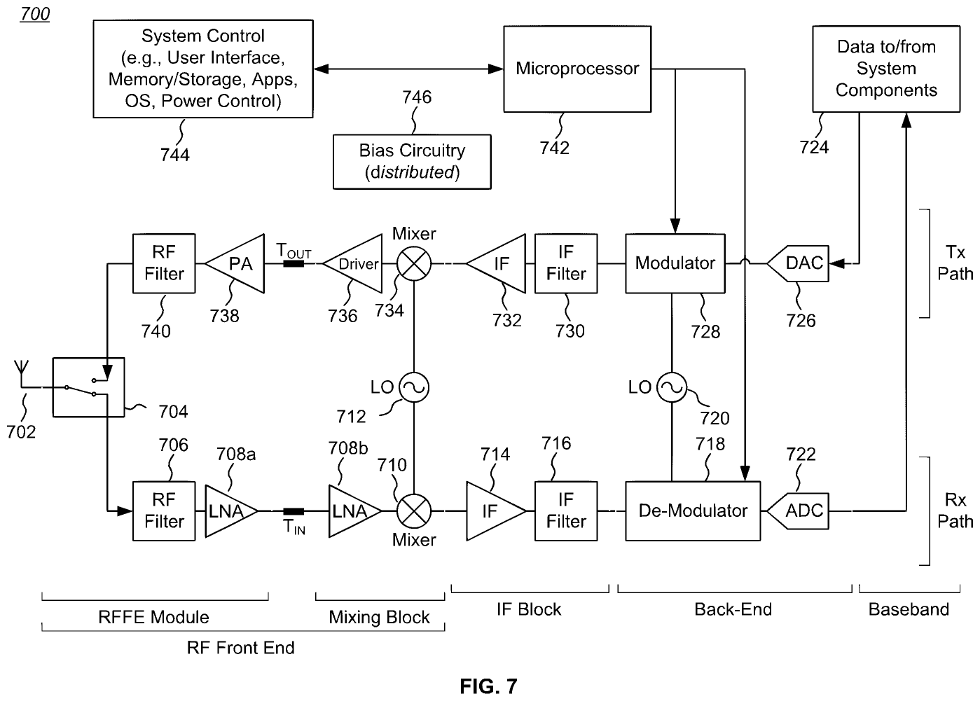

An important aspect of any wireless system is in the details of how the component elements of the system perform. FIG. 7 is a block diagram of a transceiver 700 that might be used in a wireless device, such as a cellular telephone, and which may beneficially incorporate an embodiment of the present disclosure. As illustrated, the transceiver 700 includes a mix of RF analog circuitry for directly conveying and/or transforming signals on an RF signal path, non-RF analog circuitry for operational needs outside of the RF signal path (e.g., for bias voltages and switching signals), and digital circuitry for control and user interface requirements. In this example, a receiver path Rx includes RF Front End, Intermediate Frequency (IF) Block, Back-End, and Baseband sections (noting that in some implementations, the differentiation between sections may be different). The various illustrated sections and circuit elements may be embodied in one die or multiple IC dies. For example, the RF Front End in the illustrated example may include an RFFE module and a Mixing Block, which may be embodied in (or as part of) different IC dies or modules. The different dies and/or modules may be coupled by transmission lines T_{IN} and T_{OUT} (e.g., microstrips, co-planar waveguides, or an equivalent structure or circuit), either or both of which may have, for example, a 50Ω impedance.

The receiver path Rx receives over-the-air RF signals through at least one antenna 702 and a switching unit 704, which may be implemented with active switching devices (e.g., field effect transistors or FETs) and/or with passive devices that implement frequency-domain multiplexing, such as a diplexer or duplexer. An RF filter 706 passes desired received RF signals to at least one low noise amplifier (LNA) 708a, the output of which is coupled from the RFFE Module to at least one LNA 708b in the Mixing Block (through transmission line T_{IN} in this example). The LNA(s) 708b may provide buffering, input matching, and reverse isolation. The LNAs 708a, 708b may be instances of the LNA circuit 400 shown in FIG. 3 above, LNA circuit 900 shown in FIG. 9, LNA circuit 1000 shown in FIG. 10, and/or any other amplifier circuit described herein with respect to FIGS. 1-6 and 8-12.

The output of the LNA(s) 708b is combined in a corresponding mixer 710 with the output of a first local oscillator 712 to produce an IF signal. The IF signal may be amplified by an IF amplifier 714 and subjected to an IF filter 716 before being applied to a demodulator 718, which may be coupled to a second local oscillator 720. The demodulated output of the demodulator 718 is transformed to a digital signal by an analog-to-digital converter 722 and provided to one or more system components 724 (e.g., a video graphics circuit, a sound circuit, memory devices, etc.). The converted digital signal may represent, for example, video or still images, sounds, or symbols, such as text or other characters.

In the illustrated example, a transmitter path Tx includes Baseband, Back-End, IF Block, and RF Front End sections (again, in some implementations, the differentiation between sections may be different). Digital data from one or more system components 724 is transformed to an analog signal by a digital-to-analog converter 726, the output of which is applied to a modulator 728, which also may be coupled to the second local oscillator 720. The modulated output of the modulator 728 may be subjected to an IF filter 730 before being amplified by an IF amplifier 732. The output of the IF amplifier 732 is then combined in a mixer 734 with the output of the first local oscillator 77 to produce an RF signal. The RF signal may be amplified by a driver 736, the output of which is coupled to a power amplifier (PA) 738 (through transmission line Tour in this example). The amplified RF signal may be coupled to an RF filter 740, the output of which is coupled to at least one antenna 702 through the switching unit 704.

The operation of the transceiver 700 is controlled by a microprocessor 742 in known fashion, which interacts with system control components 744 (e.g., user interfaces, memory/storage devices, application programs, operating system software, power control, etc.). In addition, the transceiver 700 will generally include other circuitry, such as bias circuitry 746 (which may be distributed throughout the transceiver 700 in proximity to transistor devices), electro-static discharge (ESD) protection circuits, testing circuits (not shown), factory programming interfaces (not shown), etc.

In modern transceivers, there are often more than one receiver path Rx and transmitter path Tx, for example, to accommodate multiple frequencies and/or signaling modalities. Further, as should be apparent to one of ordinary skill in the art, some components of the transceiver 700 may be positioned in a different order (e.g., filters) or omitted. Other components can be (and often are) added, such as (by way of example only) additional filters, impedance matching networks, variable phase shifters/attenuators, power dividers, etc.

As a person of ordinary skill in the art will understand, an RF system architecture is beneficially impacted by the current disclosure in critical ways, including reduction of non-linearities caused by low-frequency noise coupled to the input terminal INT of the amplification core 202, reduced parasitics, and improved settling times of the quiescent bias-point of the LNA circuit (e.g., as described herein with respect to FIGS. 1-12). These system-level improvements are specifically enabled by the current disclosure and enable embodiments of the disclosure to meet the strict performance specifications of customers and a number of RF standards.

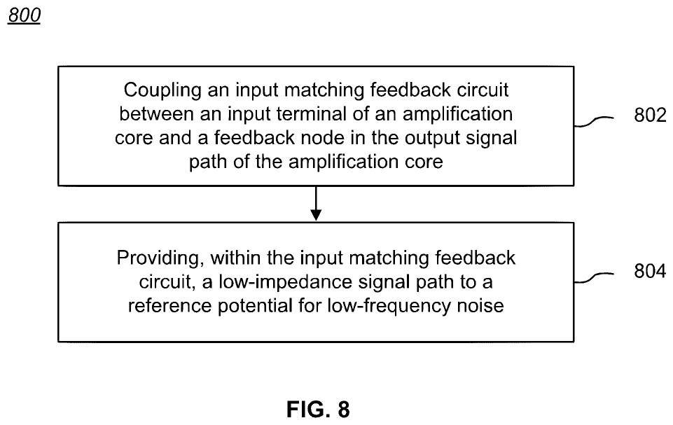

FIG. 8 is a process flow chart 800 showing a method of improving a radio frequency amplifier having an amplification core. The method includes coupling an input matching feedback circuit between an input terminal of an amplification core and a feedback node in the output signal path of the amplification core [Block 802]; and providing, within the input matching feedback circuit, a low-impedance signal path to a reference potential for low-frequency noise [Block 804]. The low-impedance signal path may include a power supply rejection resistor.

A method to improve performance of a radio frequency amplifier having an amplification core includes coupling an input matching feedback circuit between an input terminal of the amplification core and a feedback node in the output signal path of the amplification core, the input matching feedback circuit including: a first capacitor; a variable resistor coupled in series with the first capacitor; a switch coupled in series with the variable resistor; a second capacitor coupled in series with the switch; and a power supply rejection resistor coupled to a node located between the first capacitor and the variable resistor and configured to be coupled to a reference potential. Additional aspects of the above method may include modifying the circuit components implementing the method as described above and shown in FIGS. 1, 3, 9 and/or 10.

Multi-Input RF LNA with Unified Feedback Path and Passive Gain Path

FIG. 9 is a simplified schematic diagram of an embodiment of a multi-input LNA circuit 900. The LNA circuit 900 includes a plurality of inputs, LNA Input 910A, LNA Input 910B, and LNA Input 910C, each providing an input signal source (e.g., an RF signal) to a corresponding amplification core 912A, 912B, and 912C, respectively. Each amplification core 912A-C includes a common-source FET CS and a common-gate FET CG series-connected through their respective conduction channels (between drain and source) in a cascode arrangement. The gate of each common-source FET CS is an input terminal of its respective amplification core 912A-C, the source of the common-source FET CS is a degeneration terminal of its respective amplification core 912A-C, and the drain of the common-gate FET CG is an amplified-signal terminal of its respective amplification core 912A-C.

Although a three input LNA circuit 900 is illustrated, various embodiments of an LNA circuit may include two or more amplification cores, each with a corresponding input. Each amplification core may further include multiple common-gate FETS series-coupled through their respective conduction channels in a FET stack (e.g., as described with reference to FIG. 1) between the drain of the bottom-most common-gate FET CG and the amplified-signal terminal. Thus, each amplification core 912A-C may have multiple series-coupled common-gate FETs in a cascode configuration. The amplified-signal terminal would then be the drain of the upper-most common-gate FET in the respective amplification core.

It will be appreciated that FIG. 9 is a simplified circuit diagram and other circuit elements may be included in the LNA circuit 900 in various implementations, including circuit elements previously described herein with respect to FIGS. 1-8. For example, an input signal (e.g., an RF input signal) applied to one or more of the LNA input terminals may be passed through an input impedance matching circuit (which may include, for example, a series inductor and a shunt switch) which is coupled to the input terminal of the respective amplification core 912A-C. A cascode bias circuit may be configured to provide a suitable bias voltage to the common-gate FET CG and a common source bias circuit may be configured to provide a suitable bias voltage to the common-source FET CS of one or more of the amplification cores 910A-C. The bias circuits or one or more separate bias sources (not shown) may provide a suitable bias voltage or voltages to the constituent FETs within a FET stack, which is discussed in greater detail with reference to FIGS. 1 and 3.

The LNA circuit 900 further includes an LNA Output terminal 920 coupled to receive the amplified output signal generated from the LNA amplification cores 912A-C. In some embodiments, a capacitor C_{BLK} (such as, for example, capacitor C_{BLK} of FIGS. 1 and 3) may be coupled between the LNA amplification cores 912A-C (and/or a feedback node 942) and the LNA Output terminal 920, which may aid in providing output impedance matching. The LNA circuit 900 may further include an output clamp configured to clamp the amplified output signal from the amplification cores 910A-C, which may include, for example, a diode and a resistor.

A bias-isolating inductor 930A may be connected in series between a source voltage V_{DD} and the amplified-signal terminal of one or more of the amplification cores 910A-C to aid in providing output impedance matching and to provide a bias feed to the amplification cores 912A-B. Some embodiments may include a bypass switch and resistor 930B coupled in parallel with the bias-isolating inductor 930A.

A degeneration circuit 932 couples one or more of the amplification cores 912A-C to a reference potential, such as circuit ground. In some embodiments, the degeneration circuit 932 may include an adjustable degeneration inductor 932A, such as a multiport integrated circuit inductor coil. An adjustable degeneration inductor may be used to improve linearity in low gain modes. For example, a smaller value for the degeneration inductor may be used in higher-gain modes, and a larger value for the degeneration inductor may be used in lower-gain modes. Some embodiments of the degeneration circuit 932 may include a degeneration switch 932B (e.g., a bypass switch) coupled in parallel with the degeneration inductor 932A.

The LNA circuit 900 further includes a unified feedback path 940 coupling the output terminal of each amplification core 912A-C to its respective input terminal (e.g., the input terminal of each respective FET CS). More generally, the unified feedback path 940 includes a feedback path 950 and a passive gain path 960 that are coupled in parallel to a feedback node 942 located on the output signal path between the amplification cores 912A-C and the LNA output 920.

In various embodiments, the input terminal of each amplification core 912A-C is coupled to the unified feedback path 940 through an input switch SW_{IN}. As illustrated, a node 946A on the input path between LNA input 910A and the input terminal of amplification core 912A is series-coupled to the unified feedback path 940 through an input switch SW_{IN_A}. A node 946B on the input path between LNA input 910B and the input terminal of amplification core 912B is series-coupled to the unified feedback path 940 through an input switch SW_{IN_B}, and a node 946C on the input path between LNA input 910C and the input terminal of amplification core 912C is series-coupled to the unified feedback path 940 through an input switch SW_{IN_C}.

The feedback path 950 includes a resistor, such as variable resistor R_{FB} which is series-coupled between a pair of switches SW_{FB1} and SW_{FB2}. The feedback path 950 may be disabled by opening switches SW_{FB1} and SW_{FB2} and enabled by closing switches SW_{FB1} and SW_{FB2}. In some embodiments, the feedback path 950 is an input matching feedback circuit such as previously described with reference to FIGS. 3-8 (e.g., input matching feedback circuit 402), including a DC-blocking/AC-coupling first capacitor C_{FB1} series-coupled to the variable resistor R_{FB} of the feedback path 950 through switch SW_{FB2}. In some embodiments, the feedback path 950 may be implemented with a single switch SW_{FB1} (e.g., without the second switch SW_{FB2}) as illustrated, for example, in the multi-input LNA circuit 1000 of FIG. 10).

As illustrated, an optional DC-blocking/AC-coupling second capacitor C_{FB2} (e.g., capacitors C_{FB2_A}, C_{FB2_B}, and C_{FB2_C}) may be coupled to the input of each amplification core 912A-B. Each second capacitor C_{FB2_A}, C_{FB2_B}, and C_{FB2_C} may be series coupled to the variable resistor R_{FB} through feedback switch SW_{FB1} and a corresponding input switch SW_{IN} such as input switch SW_{IN_A}, input switch SW_{IN_B}, and input switch SW_{IN_C}, respectively. The first capacitor C_{FB1}, the variable resistor R_{FB}, and an input switch SW_{IN} (and optional second capacitor C_{FB2} when included in the implementation) define a feedback signal path for the respective amplification core 912A-C.

An optional power supply rejection resistor R_{PSR} may be coupled to the feedback path 950 between a node on the signal path between the first capacitor CFBI and the variable resistor R_{FB}, and the reference potential. In some embodiments, the PSR resistor R_{PSR} may be coupled at other locations in the feedback path 950, such as between the variable resistor R_{FB} and switch SW_{FB1}, or between the variable resistor and switch SW_{FB2}. As discussed, the LNA circuit 900 may be implemented without the second feedback capacitors C_{FB2} and the power supply rejection resistor R_{PSR}, which are described herein with respect to FIG. 3 to address issues caused by low frequency noise coupling into the feedback path.

The passive gain path 960 includes a circuit 962 implemented to improve return loss and stability in a low gain mode. The passive gain path 960 may further include a shunt switch coupled in series between a plurality of bypass switches to form a T-switch. As illustrated, for example, the circuit 962 includes switches S_{WPG1} and SW_{PG2} operable to enable/disable the passive gain path 960 and a switch 964 coupled to the reference potential.

The optional clamp 966 improves saturation power in the passive gain path 960 without affecting an active gain mode. For example, in a circuit with a large input power, it is often desirable to limit the output power to avoid saturation at the receiver and potential damage to the transceiver. The clamp 966 prevents the large input power from passing through the passive gain path 960 to the LNA output 920. In this approach, saturation power is constrained in low gain mode, while not affecting the active gain mode.

If a simple switch is incorporated in the passive gain path, as opposed to the T-switch of FIG. 9, the Miller effect associated with off capacitance of the switch may cause unwanted degradation of S11. The stability issue can also arise as the off capacitance of the switch starts to have significant impact due to the Miller effect.

In operation, the passive gain path 960 may be disabled by opening switches SW_{PG1} and SW_{PG2} and enabled by closing switches SW_{PG1} and SW_{PG2}. The first capacitor C_{FB1}, the circuit 962, and an input switch SW_{IN} (and optional second capacitor C_{FB2} when included in the implementation) define a passive gain path for the corresponding amplification core 912A-C.

The unified feedback path 940 combines the feedback path 950 with the passive gain path 960 across the multiple LNA inputs (e.g., LNA input 910A-C in the illustrated embodiment), reducing parasitics and improving RF performance compared to conventional approaches. The unified feedback path 940 may be configured to operate in a high gain mode, a low gain mode, and/or a passive gain mode. The high gain mode may be configured by disabling both the feedback path 950 (e.g., closing switches SW_{FB1} and SW_{FB2}) and disabling the passive gain path 960 (e.g., opening switches SW_{PG1} and SW_{PG2}). The low gain mode may be configured by enabling the feedback path 950 (e.g., opening switches SW_{FB1} and SW_{FB2}) and disabling the passive gain path 960 (e.g., opening switches SW_{PG1} and SW_{PG2}). The passive gain mode may be configured by enabling both the feedback path 950 (e.g., opening switches SW_{FB1}, SW_{FB2}), and the passive gain path 960 (e.g., opening switches SW_{PG1} and SW_{PG2}).

In some embodiments that include the second feedback capacitor C_{FB2}, the LNA circuit 900 may further include a fast charging switch, allowing the voltage across the corresponding second feedback capacitor C_{FB2} to reach a steady state at a faster rate. In the illustrated embodiment, for example, an optional fast charging switch SW_{FC_A} is coupled to a node 942A which is located on the signal path between the input switch SW_{IN_A} and the second feedback capacitor C_{FB2_A}. Similarly, an optional fast charging switch SW_{FC_B} is coupled to a node 942B, which is located on the signal path between the input switch SW_{IN_B} and the second feedback capacitor C_{FB2_B}, and an optional fast charging switch SW_{FC_C} is coupled to a node 942C, which is located on the signal path between the input switch SW_{IN_C} and the second feedback capacitor C_{FB2_C}.

In operation, closing a fast charging switch SW_{FC} pulls the node 942 to ground allowing the capacitor C_{FB2} to stabilize faster when the corresponding LNA Input 910 is enabled. After stabilization of the capacitor C_{FB2}, the fast charging switch may be opened, disconnecting the capacitor C_{FB2} from ground. In various configurations, the fast charging switch SW_{FC} may be closed for a controllable period of time to facilitate fast charging of the capacitor C_{FB2}.

The illustrated embodiment provides many advantages over an implementation with separate feedback and passive gain paths for each amplifier input. In practice, LNA implementations may operate under saturation power limitations for a low gain mode. Meeting these limitations may be challenging in multi-input LNA circuitry due in part to the arrangement of switches within the LNA. Having a separate feedback path and a separate passive gain path may require additional switches compared to the implementation of FIG. 9, introducing parasitics at the LNA inputs and degrading the LNA performance, such as via NF and return loss. The number of switches in the illustrated embodiment of FIG. 9 is significantly reduced compared to implementations with separate paths. Further, in some implementations S11 may be degraded in low gain modes, which may be caused by the Miller effect associated with Coff (off capacitance) of one or more switches.

FIG. 10 is a simplified schematic diagram of a multi-input LNA circuit 1000 in accordance with embodiments of the present disclosure. As illustrated, the LNA circuit 1000 is a multi-input LNA with three input terminals (input 1, input 2, and input 3) that are coupled to amplification circuitry 1010. It will be appreciated that while three inputs are illustrated, other numbers of inputs may be implemented in accordance with the present disclosure. The output of the amplification circuitry 1010 is coupled to a feedback path 1020 and a passive gain path 1030 (including a T-switch 1040 with optional claim 1040A) which are coupled to a plurality switches S_{IN1}, S_{IN2}, and S_{IN3}, providing a unified feedback path for the multi-input amplification circuitry 1010.

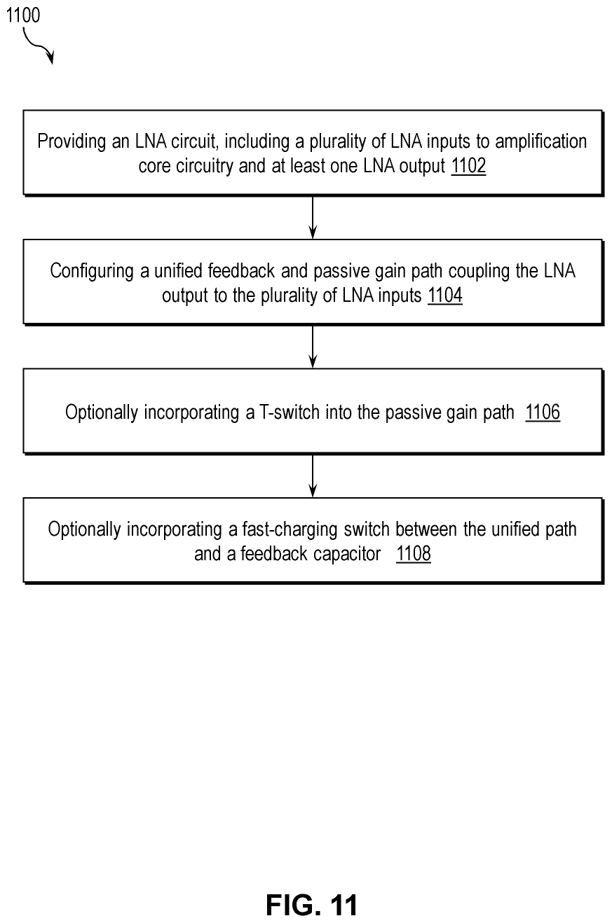

FIG. 11 is a process flow chart showing a method 1100 of improving LNA circuit performance in accordance with the present disclosure. In block 1102, an LNA circuit is provided including a plurality of LNA inputs to amplification core circuitry and at least one LNA output. In block 1104, a unified feedback path and passive gain path is configured to couple the LNA output to the plurality of LNA inputs. In this configuration, the number of switches connected to the LNA inputs (and the associated parasitics) is reduced over arrangements with separate feedback and passive gain paths. In block 1106, an optional T-switch is incorporated into the passive gain path to help improve return loss, making the active gain mode more stable when then feedback path is enabled. In some embodiments, the T-switch may include a clamp, which improves saturation power in the passive gain mode without affecting active gain mode.

In block 1108, an optional fast charging switch may be added, for example, when the implementation includes an extra capacitor, such as capacitor C_{FB2} from the implementation of FIG. 9. The extra capacitor C_{FB2} along with a PSR resistor R_{PSR} may be included, for example, to address power supply rejection ratio issues so that low frequency disturbance doesn't flow into the input. The fast charging switch may be used during gain switching to rapidly charge the capacitor C_{FB2}. Adding the optional fast charging switch enables the capacitor to reach a steady state at a faster rate than embodiments without the fast charging switch.

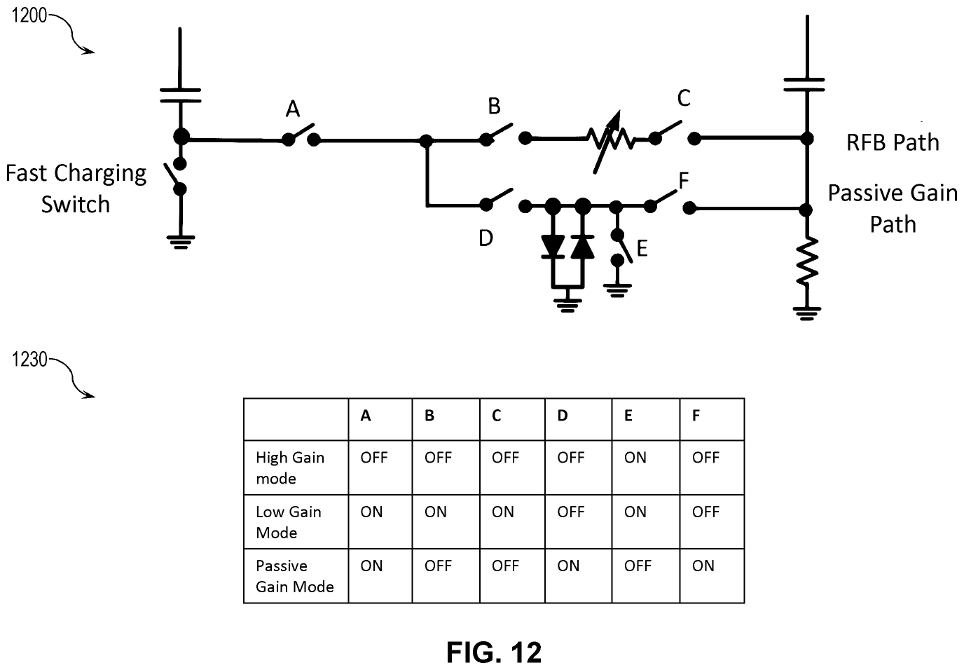

FIG. 12 illustrates example operational configurations for switches of an LNA circuit with unified feedback and passive gain paths, in accordance with the present disclosure. Circuit 1200 illustrates an example unified feedback and passive gain path for an LNA as described herein with respect to FIGS. 9-11. In operation, the switches may be controlled to implement different operating modes such as a high gain mode, a low gain mode, and a passive gain mode. Truth table 1230 illustrates switch control logic that may be implemented using control circuitry, a circuit controller, or other control system (e.g., as described herein with respect to FIGS. 1-11) to control the mode of operation.

In a high gain mode, switch A, switch B, switch C, switch D, and switch F are switched “OFF” (e.g., the switches are open), and switch E is switched “ON” (e.g., the switch is closed) connecting switch E to ground. During operation in a high gain mode, the unified path switch A is set to an open state and the feedback path and passive gain path are disabled. This switching configuration may be implemented, for example, to mitigate NF in the high gain mode.

In a low gain mode, switch A is switched “ON” enabling the unified path, and switch B and switch C are switched “ON” enabling the feedback path. The passive gain path switches D and F are “OFF,” disconnecting the passive gain path T-switch. As previous discussed herein, NF has a stricter specification requirement in high gain modes than in low gain-modes, while IIP3 usually has a higher specification requirement in the low gain mode.

In a passive gain mode, switch A is switched “ON” enabling the unified path and switch D and switch F are switched “ON” and switch F is switched “OFF” enabling the passive gain mode. In the passive gain mode, switch B and switch C of the feedback path are switched “OFF,” disabling the feedback path.

### Fabrication Technologies & Options

While the example embodiments illustrate LNAs, the circuits and methods disclosed herein may also be applied to other types of amplifiers, such as power amplifiers.

Additional well-known circuit elements that might be included in some applications, such as DC block capacitors, additional impedance matching circuitry, and additional filters, are omitted for clarity. Note also that a circuit component that is characterized as “adjustable” may have its value selected from a number of possible component value settings and fixed during fabrication, when assembled in a circuit module, during factory testing, or in the field (e.g., by burning or “blowing” fusible links), or may have its value be dynamically varied, tuned, or programmatically set, such as in response to other circuitry (e.g., temperature compensation and/or power control circuitry) or in response to generated or received command signals.

The modes of operation of the disclosed LNA circuits may be set by a control circuit (not shown) in known fashion. The control circuit may also connect to the components that are adjustable to select different component values (e.g., capacitance, resistance, inductance) for different gain states, for example, to help input and/or output impedance matching or vary gain versus linearity in some modes of operation.

The switches shown in embodiments of the present disclosure may be implemented as FETs, particularly MOSFETs. The term “MOSFET”, as used in this disclosure, includes any field effect transistor (FET) having an insulated gate whose voltage determines the conductivity of the transistor, and encompasses insulated gates having a metal or metal-like, insulator, and/or semiconductor structure. The terms “metal” or “metal-like” include at least one electrically conductive material (such as aluminum, copper, or other metal, or highly doped polysilicon, graphene, or other electrical conductor), “insulator” includes at least one insulating material (such as silicon oxide or other dielectric material), and “semiconductor” includes at least one semiconductor material.

As used in this disclosure, the term “radio frequency” (RF) refers to a rate of oscillation in the range of about 3 kHz to about 300 GHz. This term also includes the frequencies used in wireless communication systems. An RF frequency may be the frequency of an electromagnetic wave or of an alternating voltage or current in a circuit.

With respect to the figures referenced in this disclosure, the dimensions for the various elements are not to scale; some dimensions have been greatly exaggerated vertically and/or horizontally for clarity or emphasis. In addition, references to orientations and directions (e.g., “top”, “bottom”, “lower”, “upper”, “above”, “below”, “lateral”, “vertical”, “horizontal”, etc.) are relative to the example drawings, and not necessarily absolute orientations or directions.

Various embodiments of the disclosure can be implemented to meet a wide variety of specifications. Unless otherwise noted above, selection of suitable component values is a matter of design choice. Various embodiments of the disclosure may be implemented in any suitable integrated circuit (IC) technology (including but not limited to MOSFET structures), or in hybrid or discrete circuit forms. Integrated circuit embodiments may be fabricated using any suitable substrates and processes, including but not limited to standard bulk silicon, silicon-on-insulator (SOI), and silicon-on-sapphire (SOS). Unless otherwise noted above, embodiments of the disclosure may be implemented in other transistor technologies such as bipolar, BiCMOS, LDMOS, BCD, GaAs HBT, GaN HEMT, GaAs pHEMT, and MESFET technologies. However, embodiments of the disclosure are particularly useful when fabricated using an SOI or SOS based process, or when fabricated with processes having similar characteristics. Fabrication in CMOS using SOI or SOS processes enables circuits with low power consumption, the ability to withstand high power signals during operation due to FET stacking, good linearity, and high frequency operation (i.e., radio frequencies up to and exceeding 300 GHz). Monolithic IC implementation is particularly useful since parasitic capacitances generally can be kept low (or at a minimum, kept uniform across all units, permitting them to be compensated) by careful design.

Voltage levels may be adjusted, and/or voltage and/or logic signal polarities reversed, depending on a particular specification and/or implementing technology (e.g., NMOS, PMOS, or CMOS transistor devices, and enhancement mode or depletion mode transistor devices). Component voltage, current, and power handling capabilities may be adapted as needed, for example, by adjusting device sizes, serially “stacking” components (particularly FETs) to withstand greater voltages, and/or using multiple components in parallel to handle greater currents. Additional circuit components may be added to enhance the capabilities of the disclosed circuits and/or to provide additional functionality without significantly altering the functionality of the disclosed circuits.

### CONCLUSION

A number of embodiments of the disclosure have been described. It is to be understood that various modifications may be made without departing from the spirit and scope of the disclosure. For example, some of the steps described above may be order independent, and thus can be performed in an order different from that described. Further, some of the steps described above may be optional. Various activities described with respect to the methods identified above can be executed in repetitive, serial, and/or parallel fashion.

It is to be understood that the foregoing description is intended to illustrate and not to limit the scope of the disclosure, which is defined by the scope of the following claims, and that other embodiments are within the scope of the claims. In particular, the scope of the disclosure includes any and all feasible combinations of one or more of the processes, machines, manufactures, or compositions of matter set forth in the claims below. (Note that the parenthetical labels for claim elements are for ease of referring to such elements, and do not in themselves indicate a particular required ordering or enumeration of elements; further, such labels may be reused in dependent claims as references to additional elements without being regarded as starting a conflicting labeling sequence).

What is claimed is:

1. A circuit comprising:
a first amplification core comprising a first input terminal coupled to a first input signal path and a first output terminal coupled to an output signal path; and
a unified feedback path comprising:
a feedback path coupled between a feedback node in the output signal path and the first input signal path via a first input signal path switch, the feedback path comprising feedback path switches configurable to couple and/or decouple the feedback path to the first input signal path switch; and
a passive gain path couplable between the feedback node in the output signal path and the first input signal path via the first input signal path switch, the passive gain path configurable through passive gain path switches to couple and/or decouple the passive gain path to the first input signal path switch; and
wherein the first input signal path switch is configured to couple the unified feedback path to the first input terminal.

2. The circuit of claim 1, wherein the first amplification core is one of a plurality of amplification cores, the first input signal path is one of a plurality of input signal paths, and the first input signal path switch is one of a plurality of input switches;
wherein each of the plurality of amplification cores comprises an amplification core input terminal coupled to a corresponding one of the plurality of input signal paths;
wherein each of the plurality of input switches are configured to connect the unified feedback path to a corresponding one of the plurality of amplification cores.

3. The circuit of claim 1, wherein the feedback path further comprises:
a first capacitor; and
a variable resistor coupled in series with the first capacitor; and
wherein the feedback path switches are coupled in series with the variable resistor.

4. The circuit of claim 3, further comprising:
a second capacitor coupled in series with the feedback path switches; and
a power supply rejection resistor coupled to a node on the feedback path and configured to be coupled to a reference potential.

5. The circuit of claim 4, wherein the passive gain path further comprises a T-switch coupled in series between the first capacitor and the first input signal path switch.

6. The circuit of claim 4 wherein the first input signal path switch is coupled in series to the second capacitor via a first node, the circuit further comprising:
a fast charging switch coupled in series between the first node and a reference potential;
wherein the second capacitor is coupled between the first node and an LNA input voltage;
wherein the fast charging switch is configurable to connect the second capacitor to the reference potential during a state change of the unified feedback path to facilitate stabilization of the second capacitor; and
wherein the fast charging switch is configurable to decouple the capacitor from the reference potential after the second capacitor has a stabilized voltage.

7. The circuit of claim 1, wherein the unified feedback path is configurable to operate in a plurality of modes comprising:
a high gain mode wherein the feedback path switches are open and the passive gain path switches are open;
a low gain mode wherein the feedback path switches are closed, and the passive gain path switches are open; and
a passive gain mode wherein the feedback path switches are open and the passive gain path switches are closed.

8. A method comprising:
configuring a first amplification core comprising a first input terminal coupled to a first input signal path and a first output terminal coupled to an output signal path; and
configuring a unified feedback path comprising:
a first input path switch;
a feedback path couplable between a feedback node in the output signal path and the first input signal path via the first input path switch, the feedback path comprising feedback path switches configurable to couple and/or decouple the feedback path to the first input path switch; and
a passive gain path couplable between the feedback node in the output signal path and the first input signal path via the first input path switch, the passive gain path configurable to enable and/or disable the passive gain path to the first input path switch.

9. The method of claim 8, further comprising coupling a T-switch in the passive gain path to mitigate return loss, making an active gain mode more stable when the feedback path is active.

10. The method of claim 9, wherein the T-switch is further configured to include a clamp configured to saturate output power in a passive gain mode without affecting an active gain mode.

11. The method of claim 8, further comprising configuring a fast charging switch to facilitate charging a feedback capacitor during state switching;
wherein the feedback capacitor is couplable to receive a bias circuitry for the first amplification core at a first terminals and configurable to couple with a reference voltage via a fast switch circuitry and/or the unified feedback path.

12. The method of claim 8, wherein the first amplification core is one of a plurality of amplification cores, the first input signal path is one of a plurality of input signal paths, and the first input path switch is one of a plurality of input switches;
wherein each of the plurality of amplification cores comprises an amplification core input terminal coupled to a corresponding one of the plurality of input signal paths;
wherein each of the plurality of input switches are configured to connect the unified feedback path to a corresponding one of the plurality of amplification cores.

13. The method of claim 8, wherein the unified feedback path is configurable to operate in a plurality of modes comprising:
a high gain mode wherein the feedback path switches are open and the passive gain path switches are open;
a low gain mode wherein the feedback path switches are closed, and the passive gain path switches are open; and
a passive gain mode wherein the feedback path switches are open and the passive gain path switches are closed.

14. A low noise amplifier comprising:
a first amplification core comprising a first input terminal coupled to a first input signal path and a first output terminal coupled to an output signal path;
a first input signal path switch; and
a unified feedback path comprising:
a feedback path couplable between a feedback node in the output signal path and the first input signal path via the first input signal path switch, the feedback path comprising feedback path switches configurable to couple and/or decouple the feedback path to the first input signal path switch; and
a passive gain path couplable between the feedback node in the output signal path and the first input signal path via the first input signal path switch, the passive gain path configurable to connect and/or disconnect the passive gain path to/from the first input signal path switch.

15. The low noise amplifier of claim 14, wherein the feedback path further comprises:
a first capacitor; and
a variable resistor coupled in series with the first capacitor; and
wherein the feedback path switches are coupled in series with the variable resistor.

16. The low noise amplifier of claim 15, further comprising:
a second capacitor coupled in series with the feedback path switches; and
a power supply rejection resistor coupled to a node on the feedback path and configured to be coupled to a reference potential.

17. The low noise amplifier of claim 15, wherein the passive gain path further comprises a T-switch coupled in series between the first capacitor and the first input signal path switch.

18. The low noise amplifier of claim 16 wherein the first input signal path switch is coupled in series to the second capacitor via a first node, the low noise amplifier further comprising:
a fast charging switch coupled in series between the first node and a reference potential;
wherein the second capacitor is coupled between the first node and an LNA input voltage;
wherein the fast charging switch is configurable to connect the second capacitor to the reference potential during a state change of the unified feedback path to facilitate stabilization of the second capacitor; and
wherein the fast charging switch is configurable to decouple the capacitor from the reference potential after the second capacitor has a stabilized voltage.

19. The low noise amplifier of claim 14, wherein the first amplification core is one of a plurality of amplification cores, the first input signal path is one of a plurality of input signal paths, and the first input signal path switch is one of a plurality of input signal path switches;
wherein each of the plurality of amplification cores comprises an amplification core input terminal coupled to a corresponding one of the plurality of input signal paths;
wherein each of the plurality of input signal path switches are configured to connect the unified feedback path to a corresponding one of the plurality of amplification cores.

20. The low noise amplifier of claim 14, wherein the unified feedback path is configurable to operate in a plurality of modes comprising:
a high gain mode wherein the feedback path switches are open and the passive gain path switches are open;
a low gain mode wherein the feedback path switches are closed, and the passive gain path switches are open; and
a passive gain mode wherein the feedback path switches are open and the passive gain path switches are closed.
